(19) United States
(12) Patent Application Publication
(10) Pub. No.: US 2006/0151783 A1
(43) Pub. Date: Jul. 13, 2006

(54) Semiconductor integrated circuit device

(75) Inventor: Mitsuhiko Otani, Amagasaki-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/824,942

(22) Filed: Apr. 15, 2004

(30) Foreign Application Priority Data
Apr. 22, 2003 (JP) 2003-116866

(51) Int. Cl. H01L 23/58

(52) U.S. Cl. 257/48

(57) ABSTRACT

A semiconductor integrated circuit device includes a digital circuit part and an analog circuit part that are disposed on a surface of one semiconductor substrate. A dummy layer part made of polysilicon that is the same as polysilicon composing a gate of a transistor is disposed between the digital circuit part and the analog circuit part. The distance between a n-well region in the digital circuit part and a n-well region in the analog circuit part is increased, and a resistance component of the substrate is increased. Accordingly, a parasitic current ic drawn from a back gate of the analog circuit part is decreased and the fluctuation of an electric potential is decreased. In addition, a polysilicon layer disposed for adjusting an area ratio of polysilicon to be constant can be utilized as the dummy layer part, thus suppressing an increase of the chip size.

### FIELD OF THE INVENTION

The present invention relates to a semiconductor integrated circuit device having a digital circuit for driving sensor arrays such as a CCD (Charge Coupled Device) area sensor, a CCD linear sensor or a CMOS sensor, and an analog circuit for processing a signal output from the sensor array, which are provided on one semiconductor substrate.

### BACKGROUND OF THE INVENTION

FIG. 6 is a plan view showing an outline of a conventional semiconductor integrated circuit device. On a surface of one semiconductor substrate (semiconductor chip) 1, a digital circuit part 2 including, for example, a CMOS digital circuit and an analog circuit part 3 are disposed close to each other. On the side where the digital circuit part and the analog circuit part are not adjacent to each other, a dummy layer part 4 made of polysilicon (PS) is disposed. The dummy layer part 4 is provided for adjusting an area ratio of polysilicon on the chip to be constant in order to keep an etching treatment time constant in a semiconductor manufacturing process for forming a gate of a CMOS transistor made of polysilicon.

FIG. 7 is a cross sectional view taken along line C-C of FIG. 6. The digital circuit part 2 includes at least one pair of a p-type MOS transistor and a n-type MOS transistor, the p-type MOS transistor being disposed in a n-well region 6 that forms a back gate and the n-type MOS transistor being disposed in a p-well region 9 that forms a back gate. The p-type MOS transistor is composed of a pair of p+ type channel buried layers 7 and a polysilicon layer 8 as a gate electrode. The n-type MOS transistor is composed of a pair of n+ type channel buried layers 10 and a polysilicon layer 11 as a gate electrode.

The analog circuit part 3 includes at least one pair of a p-type MOS transistor and a n-type MOS transistor, the p-type MOS transistor being disposed in a n-well region 12 that forms a back gate and the n-type MOS transistor being disposed in a p-well region 15 that forms a back gate. The p-type MOS transistor is composed of a pair of p+ type channel buried layers 13 and a polysilicon layer 14 as a gate electrode. The n-type MOS transistor is composed of a pair of n+ type channel buried layers 16 and a polysilicon layer 17 as a gate electrode.

It is known that when a signal switches from High level to Low level or Low level to High level in a CMOS digital circuit, a through-current flows, thus leading to the case where an electric potential of a channel transiently may be lower than the ground potential or higher than a power-supply potential. When such a phenomenon occurs in a semiconductor integrated circuit, a parasitic transistor is formed in the semiconductor integrated circuit, and thus a parasitic current flows. In the case where the digital circuit part and the analog circuit part are disposed close to each other on a surface of one semiconductor substrate (semiconductor chip), circuit properties of the analog circuit part deteriorate due to the influence of the parasitic current.

That is to say, as shown in FIG. 7, a parasitic transistor 18 is formed with a substrate 1 as a base, the n-well region 6 of the digital circuit part 2 as an emitter, and the n-well region 12 of the analog circuit part 3 as a collector. Since the distance between the n-well region 6 and the n-well region 12 is small and a resistance component of the substrate 1 between those regions is small, a reverse hFE of the parasitic transistor 18 is large, and a parasitic current ic drawn from the n-well region 12 that forms a back gate of the analog circuit part 3 also is large. When this parasitic current ic is increased, the fluctuation of an electric potential of the n-well region 12 becomes relatively large, and thus the deterioration of the circuit properties of the analog circuit part 3 becomes remarkable.

The magnitude of the reverse hFE of the parasitic transistor 18 is determined by the distance between the digital circuit part 2 and the analog circuit part 3. The larger the distance is, the smaller the reverse hFE becomes due to the resistance component of the substrate 1. Accordingly, the parasitic current ic also becomes small. When this parasitic current ic is small, the fluctuation of the electric potential of the n-well region 12 can be made small, so that the deterioration of the circuit properties of the analog circuit part 3 can be avoided. Therefore, the structure with a large distance between the digital circuit part 2 and the analog circuit part 3, as shown in FIG. 8, is thought to be effective. JP56(1981)-98839A or JP7(1995)-135299A discloses a diffusion region disposed for separating two kinds of circuit regions that form the parasitic transistor so as to prevent the deterioration of the circuit properties due to the parasitic transistor. However, the simple provision of a separating region may increase the chip size correspondingly.

### SUMMARY OF THE INVENTION

It is an object of the present invention to provide a semiconductor integrated circuit device, in which the deterioration of circuit properties of an analog circuit part disposed on a semiconductor substrate (semiconductor chip) can be suppressed without increasing a size of the chip. The deterioration results from an electric potential of a channel being transiently lower than the ground potential or higher than a power-supply potential, due to a through-current of a digital circuit part disposed on the common semiconductor substrate.

The semiconductor integrated circuit device of the present invention includes a digital circuit part and an analog circuit part that are disposed on a surface of one semiconductor substrate, and a dummy layer part made of polysilicon that is the same as polysilicon composing a gate of a transistor is disposed between the digital circuit part and the analog circuit part.

### BRIEF DESCRIPTION OF THE DRAWINGS

FIG. 1 is a plan view showing the semiconductor integrated circuit device according to Embodiment 1 of the present invention.

FIG. 2 is a cross sectional view taken along line A-A of FIG. 1.

FIG. 3 is a plan view showing the semiconductor integrated circuit device according to Embodiment 2.

FIG. 4 is a cross sectional view taken along line B-B of FIG. 3.

FIG. 5 is a block diagram showing the camera according to Embodiment 3.

FIG. 6 is a plan view showing the semiconductor integrated circuit device according to a conventional example.

FIG. 7 is a cross sectional view taken along line C-C of FIG. 6.

FIG. 8 is a plan view showing the semiconductor integrated circuit device according to another conventional example.

### DESCRIPTION OF THE PREFERRED EMBODIMENTS

The semiconductor integrated circuit device of the present invention has a structure in which a dummy layer part made of polysilicon that is the same as polysilicon composing a gate of a transistor is disposed between a digital circuit part and an analog circuit part that are disposed on a surface of one semiconductor substrate. Thereby the distance between a n-well region in the digital circuit part and a n-well region in the analog circuit part is increased. Thus, a resistance component of the substrate increases, and a reverse hFE of a parasitic transistor can be decreased. Therefore, a parasitic current ic drawn from a back gate of the analog circuit part decreases, and a fluctuation of an electric potential of the n-well region in the analog circuit part is decreased, thus suppressing a deterioration of circuit properties of the analog circuit part. In addition, since a polysilicon layer that is disposed for adjusting an area ratio of polysilicon on a chip to be constant can be utilized as the dummy layer part, the increase of the chip size can be suppressed.

In the semiconductor integrated circuit device with the above-described structure, it is preferable that a dummy region further is provided between the digital circuit part and the analog circuit part, and that a power-supply potential is applied to the dummy region.

The digital circuit part may be structured as a circuit for driving a sensor array, and the analog circuit part may be structured as a circuit for analog processing an image detecting signal that is output from the sensor array. The sensor array may be a CCD area sensor, a CCD linear sensor or a CMOS sensor.

A camera may be provided that includes an imaging element and a semiconductor integrated circuit device provided with: a digital circuit part for driving the imaging element; and an analog circuit part for analog processing an image detecting signal that is output from the imaging element. The semiconductor integrated circuit device may be structured as described above.

The semiconductor integrated circuit device according to embodiments of the present invention will be described below in detail with reference to the drawings.

### Embodiment 1

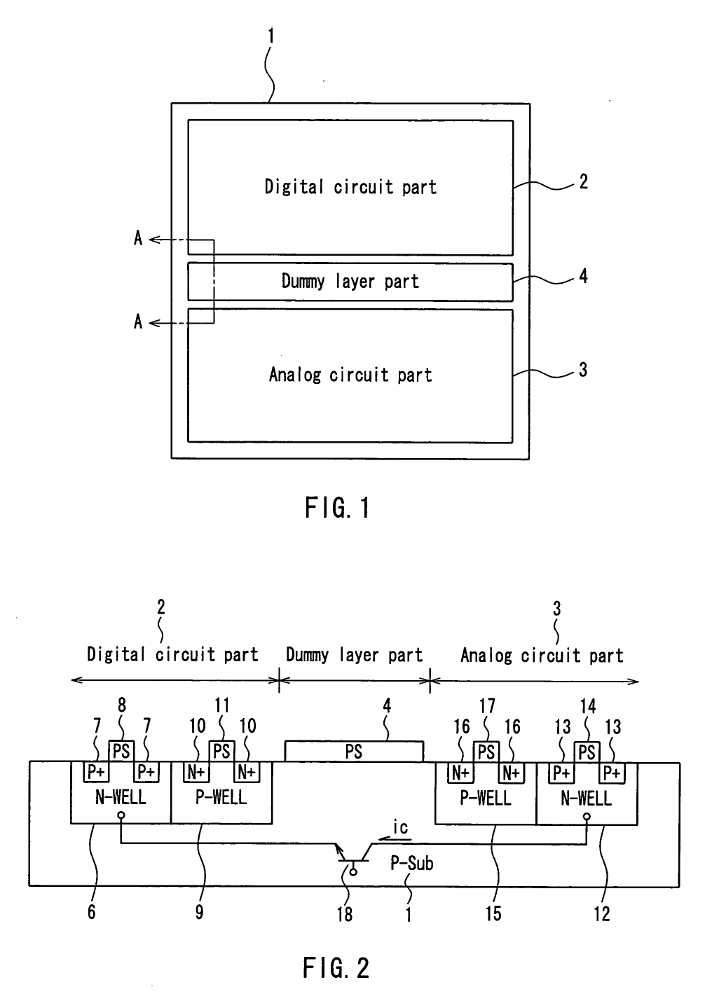

FIG. 1 is a plan view showing the semiconductor integrated circuit device according to Embodiment 1. This circuit is an example of integrating a driving timing generator circuit of a CCD area sensor as an example and an analog pre-treatment circuit.

A digital circuit part 2 and an analog circuit part 3 are disposed on a surface of a p-type semiconductor substrate (semiconductor chip) 1, and a dummy layer part 4 made of polysilicon is inserted into the region therebetween. The digital circuit part 2 generates pulse signals that control a driving timing for horizontal scanning and vertical scanning of the CCD area sensor, a high-speed pulse timing for a horizontal driving circuit, an analog pre-treatment, and the like. The analog circuit part 3 includes a circuit for removing noise from an image signal output from the CCD area sensor, a circuit for adjusting an amplitude of the signal, an AD converter circuit for digitalizing the signal, and the like. The dummy layer part 4 is disposed for adjusting an area ratio of polysilicon on the chip to be constant in order to keep an etching treatment time constant in a semiconductor manufacturing process for forming a gate of a CMOS transistor made of polysilicon.

FIG. 2 is a cross sectional view taken along line A-A of FIG. 1. The digital circuit part 2 includes at least one pair of a p-type MOS transistor and a n-type MOS transistor, the p-type MOS transistor being disposed in a n-well region 6 that forms a back gate and the n-type MOS transistor being disposed in a p-well region 9 that forms a back gate. The p-type MOS transistor is composed of a pair of p+ type channel buried layers 7 and a polysilicon layer 8 as a gate electrode, which is disposed away from the analog circuit part 3. The n-type MOS transistor is composed of a pair of n+ type channel buried layers 10 and a polysilicon layer 11 as a gate electrode.

The analog circuit part 3 includes at least one pair of a p-type MOS transistor and a n-type MOS transistor, the p-type MOS transistor being disposed in a n-well region 12 that forms a back gate and the n-type MOS transistor being disposed in a p-well region 15 that forms a back gate. The p-type MOS transistor is composed of a pair of p+ type channel buried layers 13 and a polysilicon layer 14 as a gate electrode, which is disposed away from the digital circuit part 2. The n-type MOS transistor is composed of a pair of n+ type channel buried layers 16 and a polysilicon layer 17 as a gate electrode.

According to the arrangement mentioned above, since the distance between the n-well region 6 in the digital circuit part 2 that functions as an emitter of a parasitic transistor 18 and the n-well region 12 in the analog circuit part 3 that functions as a collector of the parasitic transistor 18 is large, a resistance component of the substrate is increased, thus a reverse hFE of the parasitic transistor 18 can be decreased. Therefore, a parasitic current ic drawn from the back gate of the analog circuit part 3 is decreased, and the fluctuation of an electric potential of the n-well region 12 in the analog circuit part 3 is decreased, thus suppressing a deterioration of circuit properties of the analog circuit part 3.

### Embodiment 2

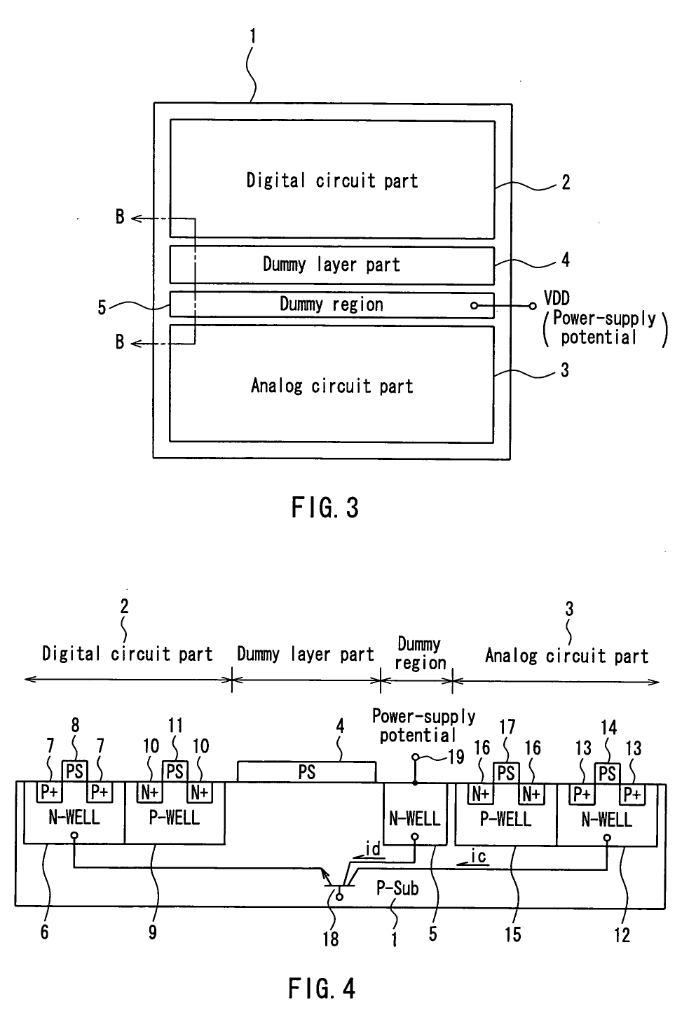

FIG. 3 is a plan view of the semiconductor integrated circuit device according to Embodiment 2. FIG. 4 is a cross sectional view taken on line B-B of FIG. 3.

According to this embodiment, a n-well dummy region 5 further is disposed between a dummy layer part 4 and an analog circuit part 3, and a power-supply potential 19 is applied to this dummy region 5. Thereby, most of a collector current of a parasitic transistor 18, which is represented by id, is supplied from this dummy region 5. In addition, since the distance between a digital circuit part 2 and the analog circuit part 3 further is increased, a parasitic current ic drawn from a back gate of the analog circuit part 3 further is decreased. Consequently, the fluctuation of an electric potential of a n-well region 12 in the analog circuit part 3 further is decreased, thus suppressing a deterioration of circuit properties of the analog circuit part 3 more effectively.

According to the above-noted embodiment, the fluctuation of the electric potential of the n-well region 12 that forms the back gate of a p-type MOS transistor in the analog circuit part 3 becomes exceedingly small. Therefore, the deterioration of the circuit properties of the analog circuit part 3 can be suppressed sufficiently. Accordingly, the combination of an imaging element using a CCD area sensor or a CMOS sensor and the semiconductor integrated circuit device of the above-described embodiment provides a high-performance camera with small image degradation that would be caused by the deterioration of the circuit properties of the analog circuit.

In addition, this configuration can eliminate the necessity for disposing the dummy layer part 4 at the other region on the semiconductor substrate 1 for adjusting an area ratio of polysilicon on a chip to be constant, thus avoiding the increase of the chip size therefor and also suppressing the increase of cost.

### Embodiment 3

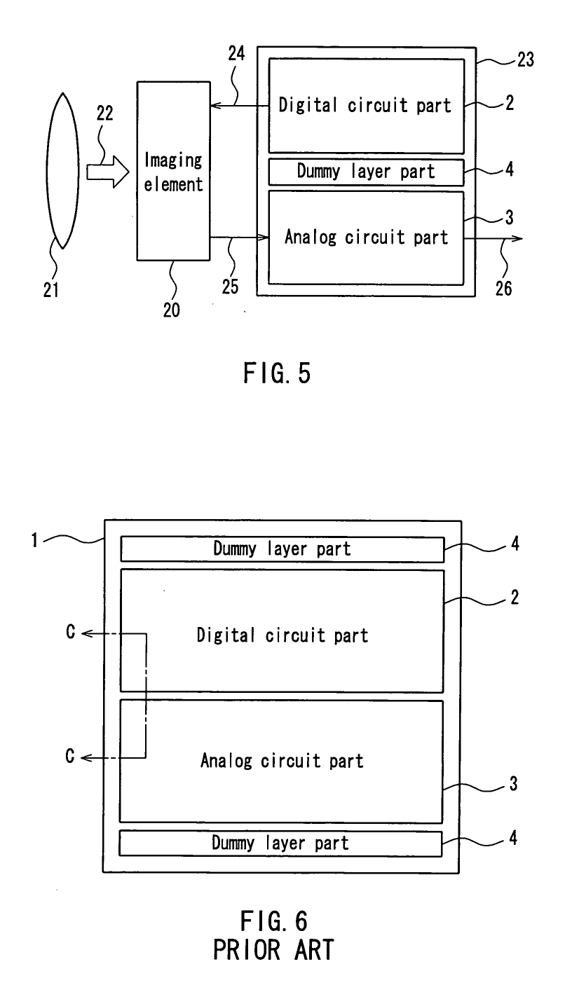

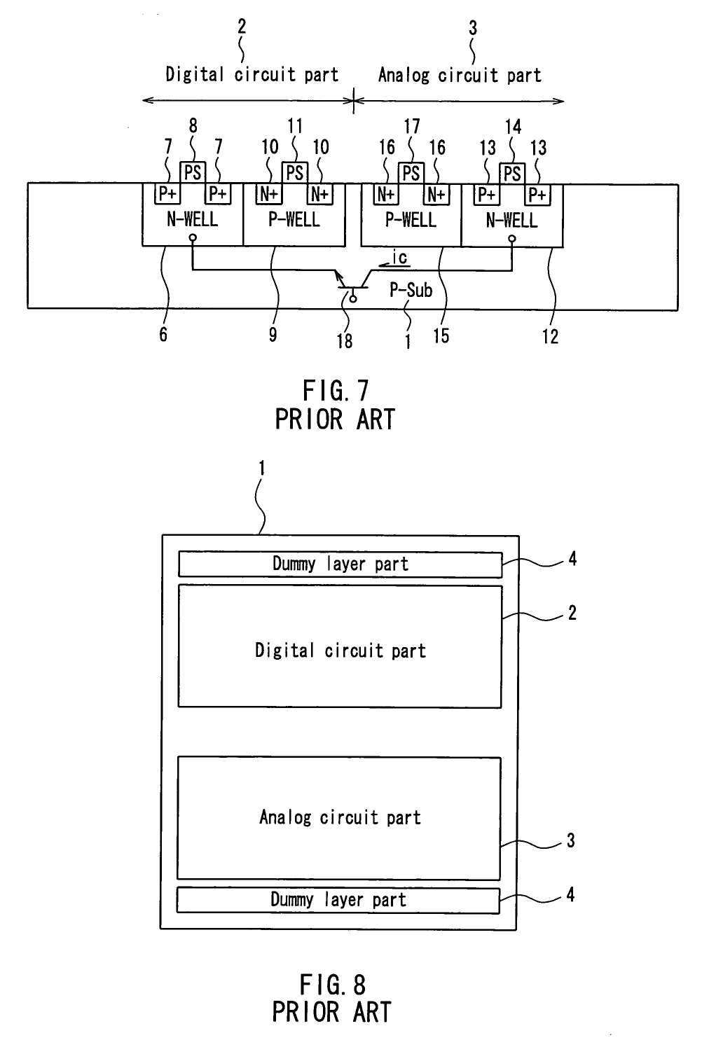

FIG. 5 shows a schematic structure of a camera according to Embodiment 3, which is an example using the semiconductor integrated circuit device with the structure of the above-noted embodiments.

Reference numeral 20 denotes an imaging element that is configured using a CCD area sensor or a CMOS sensor. On a photodetector (not shown in the figure) of the imaging element 20, an optical image is formed by light 22 that is focused by an optical system 21. A semiconductor integrated circuit device 23 has any one of the structures of the above-noted embodiments, in which a digital circuit part 2 supplies a driving signal 24 for the imaging element 20. An image detecting signal 25 that is output from the imaging element 20 is supplied to an analog circuit part 3 of the semiconductor integrated circuit device 23, and subsequently is output as an imaging signal 25.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor integrated circuit device, comprising a digital circuit part and an analog circuit part that are disposed on a surface of one semiconductor substrate,
wherein a dummy layer part made of polysilicon that is the same as polysilicon composing a gate of a transistor is disposed between the digital circuit part and the analog circuit part.

2. The semiconductor integrated circuit device according to claim 1,
wherein a dummy region further is provided between the digital circuit part and the analog circuit part, and
a power-supply potential is applied to the dummy region.

3. The semiconductor integrated circuit device according to claim 1,
wherein the digital circuit part is a circuit for driving a sensor array, and
the analog circuit part is a circuit for analog processing an image detecting signal that is output from the sensor array.

4. The semiconductor integrated circuit device according to claim 3, wherein the sensor array is a CCD area sensor, a CCD linear sensor or a CMOS sensor.

5. A camera, comprising:
an imaging element; and
a semiconductor integrated circuit device comprising a digital circuit part for driving the imaging element and an analog circuit part for analog processing an image detecting signal output from the imaging element,
wherein the semiconductor integrated circuit device has a structure in which a dummy layer part made of polysilicon that is the same as polysilicon composing a gate of a transistor is disposed between the digital circuit part and the analog circuit part.
